(19) United States
(12) Patent Application Publication
(10) Pub. No.: US 2008/0102577 A1
(43) Pub. Date: May 1, 2008

(54) Method for Preparing a Trench Capacitor Structure

(75) Inventors: Su Chen Lai, Hsinchu City (TW); Hung-Kwei Liao, Taoyuan County (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 11/564,191

(22) Filed: Nov. 28, 2006

(30) Foreign Application Priority Data
Oct. 25, 2006 (TW) 095139294

(51) Int. Cl. H01L 21/8242

(52) U.S. Cl. 438/243

(57) ABSTRACT

A method for preparing a trench capacitor structure first forms at least one trench in a substrate, and forms a buried bottom electrode on the lower outer surface of the trench. A dielectric layer is formed to cover an inner sidewall of the trench, and a plurality of deposition processes are then performed to form several polysilicon layers in the trench, wherein a process of introducing a gas containing dopants into the trench is performed at an interval of these deposition processes to diffuse the dopants into the polysilicon layers. Afterward, a planarization process and an anisotropic dry etching process are performed to remove a portion of the polysilicon layers from the top portion of the trench to form a top electrode in the lower portion of the trench. A collar insulation layer is then formed on the upper sidewall of the trench, and the collar insulation layer is used as an implanting mask to perform an implanting process to implant the dopants into the top electrode.

### BACKGROUND OF THE INVENTION

(A) Field of the Invention

The present invention relates to a method for preparing a trench capacitor structure, and more particularly, to a method for preparing a trench capacitor structure capable of reducing the resistance of the capacitor.

(B) Description of the Related Art

A memory unit of a dynamic random access memory (DRAM) includes an access transistor and a storage capacitor, wherein a source of the access transistor is connected to a top electrode of the storage capacitor, and a bottom electrode of the storage capacitor is connected to a positive voltage. In particular, as the quantity of charges stored on the capacitor increases, the occurrence of read errors by a read amplifier when reading data caused by noises can be greatly reduced. Therefore, a memory unit of the current DRAM usually adopts a stacked capacitor of three-dimensional structure or a trench capacitor structure to increase the accumulated charges on the capacitor.

FIG. 1 is a cross-sectional view of a trench capacitor structure 10 according to the prior art. The trench capacitor structure 10 includes a silicon substrate 12, two trenches 14 disposed in the silicon substrate 12, a bottom electrode 16 disposed on the outer surface of the trench 14, a dielectric layer 18 disposed on the inner surface of the bottom electrode 16, a top electrode 20 disposed on the surface of the dielectric layer 18, a collar oxide layer 22 disposed on the inner surface of the trenches 14, a buried conductive stripe 24 disposed on the top electrode 20 and a shallow trench isolation 26 filled with dielectric material. The bottom electrode 16, the dielectric layer 18 and the top electrode 20 in the trench 14 form a capacitor 30.

In general, the method for preparing the top electrode 20 is as follows. First a polysilicon layer filling each trench 14 is formed of a deposition process, and an etch back process is performed to remove a portion of the polysilicon layer from the top portion of the trench 14 and the polysilicon layer on the surface of the silicon substrate 12 so as to form the top electrode 20 in the lower portion of the trench 14. However, the resistance of the polysilicon is relatively high, and the parasitic capacitance of the polysilicon and the trench capacitor 10 may produce an RC-delay effect, which limits the operating speed of the DRAM.

### SUMMARY OF THE INVENTION

One aspect of the present invention provides a method for preparing a trench capacitor structure capable of reducing the resistance of the capacitor by increasing the concentration of dopants of a top electrode disposed in the trench.

A method for preparing a trench capacitor structure according to this aspect of the present invention first forms at least one trench in a substrate, and then forms a buried bottom electrode on the lower outer surface of the trench. A dielectric layer is formed to cover an inner sidewall of the trench, and a plurality of deposition processes are then performed to form several polysilicon layers in the trench, wherein a process of introducing a gas containing dopants into the trench is performed at an interval of these deposition processes to diffuse the dopants into the polysilicon layers. Afterward, a planarization process and an anisotropic dry etching process are performed to remove a portion of the polysilicon layers from the top portion of the trench to form a top electrode in the lower portion of the trench. A collar insulation layer is then formed on the upper sidewall of the trench, and the collar insulation layer is used as an implanting mask to perform an implanting process to implant the dopants into the top electrode.

Compared with the prior art, the present invention performs a plurality of deposition processes to form several polysilicon layers and a process of introducing a gas containing dopants into the trench at the interval of these deposition processes to diffuse the dopants into the polysilicon layers so as to form a top electrode with low resistance. Moreover, the present invention also adopts a collar insulation layer as an implanting mask to perform an implanting process to implant the dopants into the top electrode so as to further reduce the resistance of the top electrode.

### BRIEF DESCRIPTION OF THE DRAWINGS

The objectives and advantages of the present invention will become apparent upon reading the following description and upon reference to the accompanying drawings in which:

FIG. 1 is a cross-sectional view of a trench capacitor structure according to the prior art; and

FIG. 2 to FIG. 14 illustrate a method for preparing a trench capacitor structure according to one embodiment of the present invention.

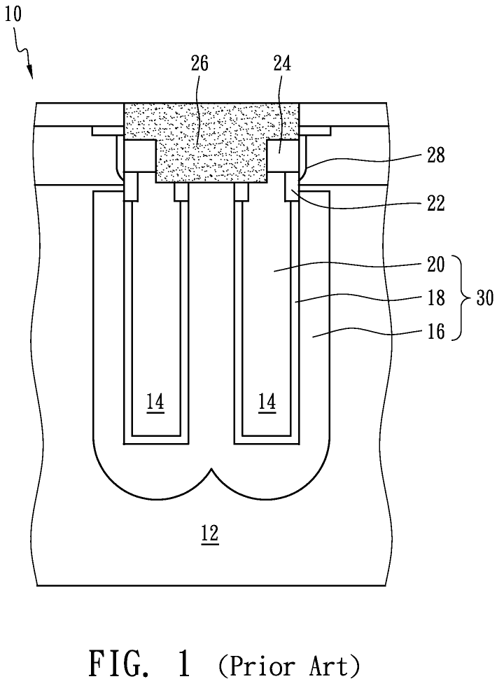

### DETAILED DESCRIPTION OF THE INVENTION

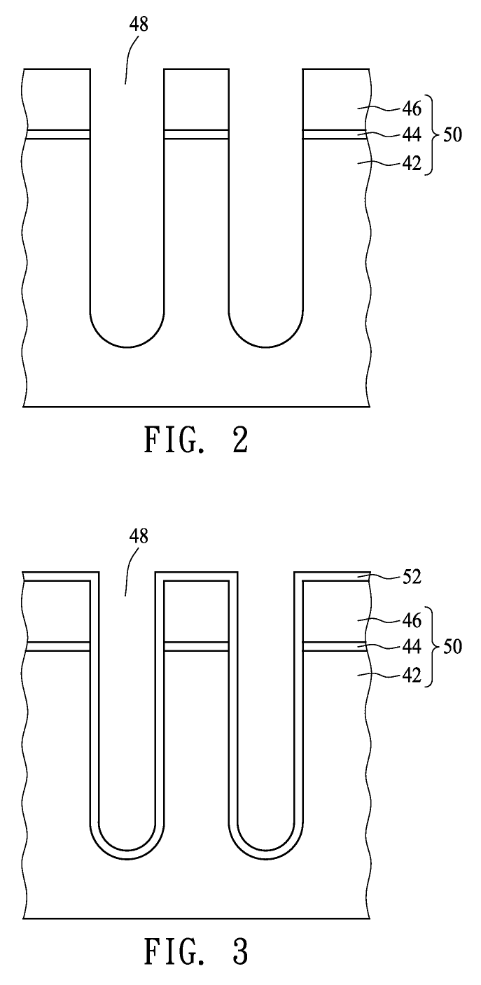

FIG. 2 to FIG. 14 illustrate a method for preparing a trench capacitor structure according to one embodiment of the present invention. First, at least one trench 48 is formed in a substrate 50. The substrate 50 includes a semiconductor substrate 42 such as a silicon substrate, a silicon oxide layer 44 and a silicon nitride layer 46. A deposition process is then performed to form a dielectric layer 52 containing dopants in the trench 48, wherein the dielectric layer 52 covers the inner wall of the trench 48 and the surface of the substrate 50, as shown in FIG. 3. The dielectric layer 52 can be formed of arsenic silicon glass (ASG), and the dopants are arsenic ions.

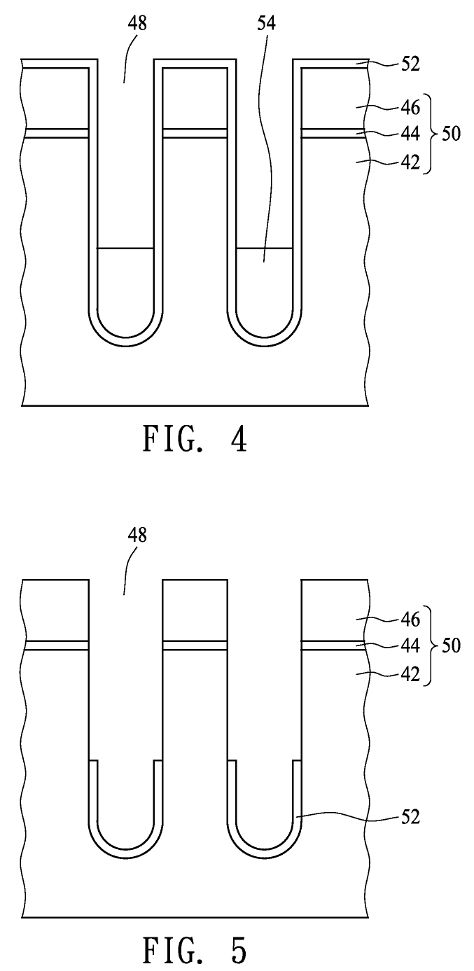

Referring to FIG. 4, a spin-coating process is performed to form a photoresist layer 54 filling the trench 48, and an anisotropic dry etching process is then performed to remove a portion of the photoresist layer 54 to a predetermined depth. Afterward, a wet etching process, using the photoresist layer 54 as an etching mask and the buffered hydrofluoric acid as an etching solution, is performed to remove a portion of the dielectric layer 52 above the photoresist layer 54 such that the dielectric layer 52 covers only the lower inner surface of the trench 48, and the photoresist layer 54 in the trench 48 is then completely removed, as shown in FIG. 5.

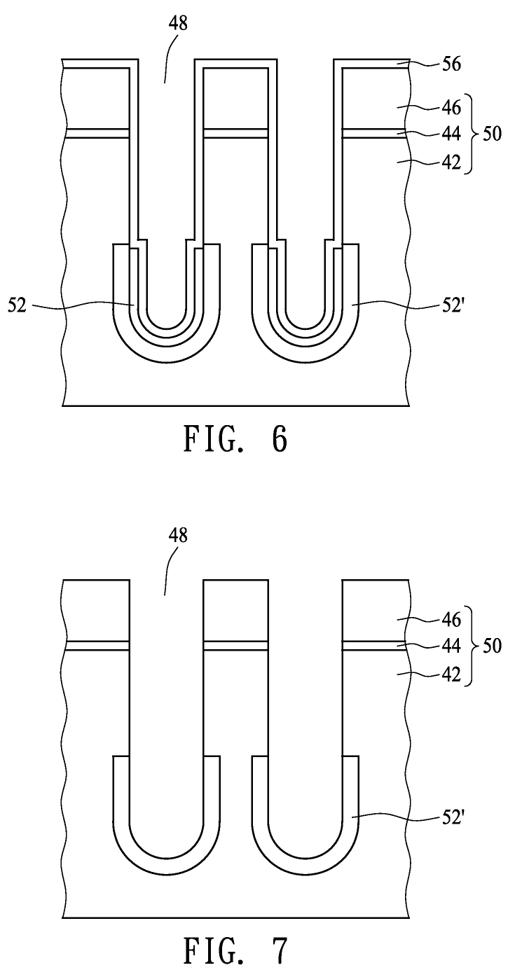

Referring to FIG. 6, a deposition process is performed to form a dielectric layer 56 covering the dielectric layer 52 and the inner sidewall of the trench 48, wherein the dielectric layer 56 can be formed of tetra-ethyl-ortho-silicate (TEOS). A thermal treatment process is then performed to diffuse the dopants of the dielectric layer 52 into the semiconductor substrate 42 on the lower outer surface of the trench 48 so as to form a buried bottom electrode 52′ on the lower outer surface of the trench 48. Subsequently, a wet etching process using buffered hydrofluoric acid as the etching solution is performed to remove the dielectric layer 52 and the dielectric layer 56, as shown in FIG. 7.

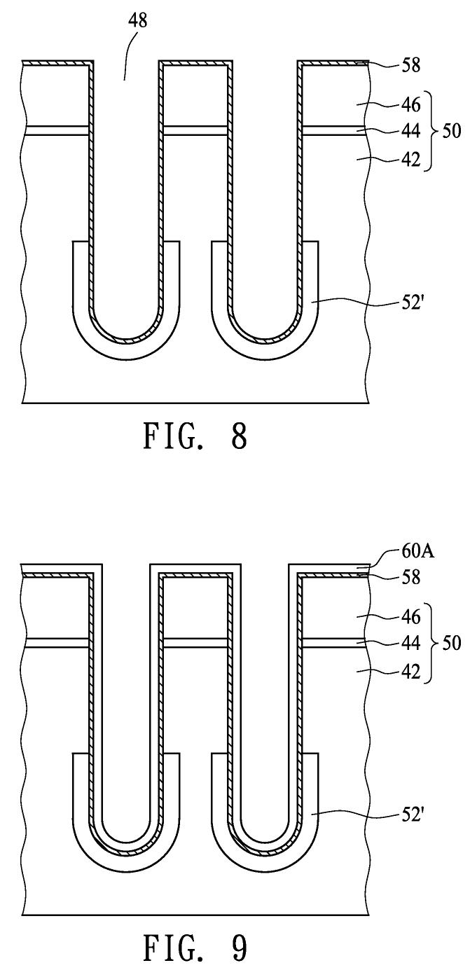

Referring to FIG. 8, a deposition process is performed to form a dielectric layer 58 covering the inner wall of the trench 48, wherein the dielectric layer 58 can be a laminated dielectric structure of silicon oxide-silicon nitride or a laminated dielectric structure of silicon oxide-silicon nitride-silicon oxide (ONO). Afterward, a deposition process is performed to form a polysilicon layer 60A covering the dielectric layer 58, and a process of introducing a gas containing dopants into the trench 48 is performed to diffuse the dopants into the polysilicon layer 60A such that the polysilicon layer 60A becomes a conductive layer, as shown in FIG. 9. The dopants can be N⁺ type, for example, arsenic ions.

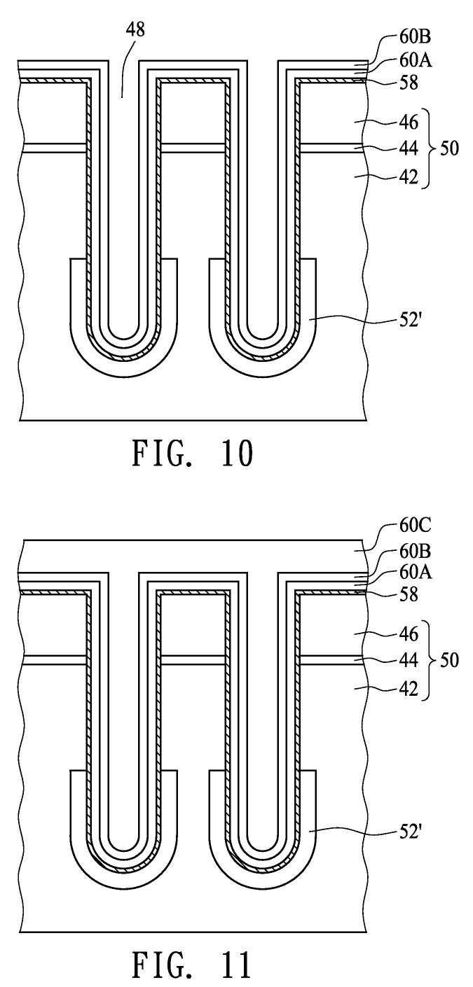

Referring to FIG. 10, a deposition process is performed to form a polysilicon layer 60B covering the polysilicon layer 60A, and a process of introducing a gas containing dopants into the trench 48 is performed to diffuse the dopants into the polysilicon layer 60B such that the polysilicon layer 60B becomes a conductive layer. Afterward, a deposition process is performed to form a polysilicon layer 60C filling the trench 48, as shown in FIG. 11.

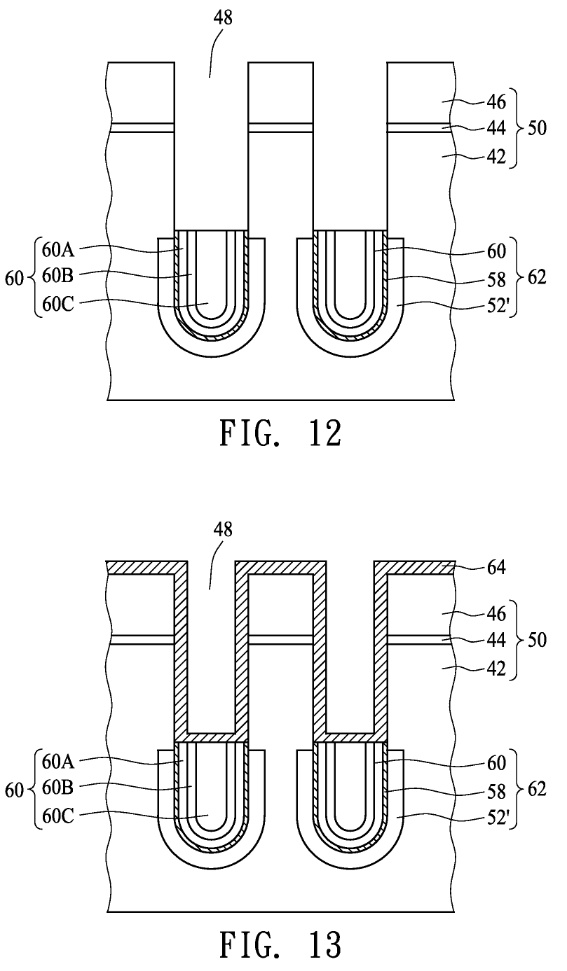

Referring to FIG. 12, an etching process is performed to remove a portion of the polysilicon layers 60A, 60B, 60C above the substrate 50, and an anisotropic dry etching process is then performed to remove a portion of the polysilicon layers 60A, 60B, 60C in the trench 48 so as to form a top electrode 60 filling the lower portion of the trench 48. In particular, the buried bottom electrode 52′, the dielectric layer 58 and the top electrode 60 form a capacitor 62 in the lower portion of the trench 48.

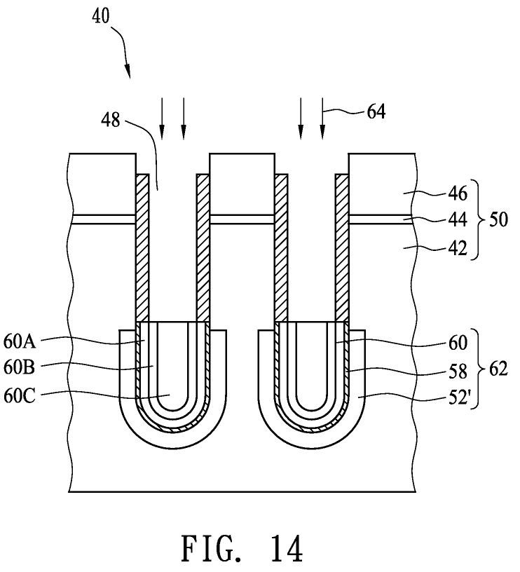

Referring to FIG. 13, a deposition process is performed to form a collar insulation layer 64 on the upper sidewall of the trench 48 and on the surface of the substrate 50, wherein the collar insulation layer 64 can be formed of silicon oxide. An anisotropic dry etching process is then performed to remove a portion of the collar insulation layer 64 on the surface of the substrate 50 to reduce the height of the collar insulation layer 64 to be lower than the surface of the substrate 50. An implanting process, using the silicon nitride layer 46 and the collar insulation layer 64 as an implanting mask, is performed to implant the dopants 64 into the top electrode 60 to complete the trench capacitor structure 40, as shown in FIG. 14. The dopants 64 can be N⁺ type, for example, arsenic ions, and the dopants 64 implanted into the top electrode 60 can be used as charge carriers for reducing the resistance value of the top electrode 60.

Compared with the prior art, the present invention performs a plurality of deposition processes to form the polysilicon layers 60A, 60B, 60C, and performs a process of introducing a gas containing dopants into the trench 48 at the interval of these deposition processes to diffuse the dopants into the polysilicon layers 60A, 60B so as to form the top electrode 60 with low resistance. Moreover, the present invention also adopts the silicon nitride layer 46 and the collar insulation layer 64 as an implanting mask to perform an implanting process to implant the dopants 64 into the top electrode 60 so as to further reduce the resistance of the top electrode 60.

The above-described embodiments of the present invention are intended to be illustrative only. Numerous alternative embodiments may be devised by those skilled in the art without departing from the scope of the following claims.

What is claimed is:

1. A method for preparing a trench capacitor structure, comprising the steps of:
forming at least one trench in a substrate;
forming a buried bottom electrode on a lower outer surface of the trench;
forming a dielectric layer covering an inner sidewall of the trench;
forming a top electrode in a lower portion of the trench;
forming a collar insulation layer on an upper sidewall of the trench; and
performing an implanting process to implant dopants into the top electrode.

2. The method for preparing a trench capacitor structure of claim 1, wherein the dopants are N⁺ type.

3. The method for preparing a trench capacitor structure of claim 2, wherein the dopants are arsenic ions.

4. The method for preparing a trench capacitor structure of claim 1, wherein the step of forming a top electrode in a lower portion of the trench comprises:
performing a plurality of deposition processes; and
introducing a gas containing dopants into the trench at an interval of these deposition processes.

5. The method for preparing a trench capacitor structure of claim 4, wherein the deposition processes form polysilicon layers on the inner sidewall of the trench, and the dopants are diffused into the polysilicon layers.

6. The method for preparing a trench capacitor structure of claim 1, wherein the step of forming a top electrode in a lower portion of the trench comprises:
performing a first deposition process to form a first polysilicon layer on the inner sidewall of the trench;
introducing a gas containing dopants into the trench to diffuse the dopants into the first polysilicon layer;
performing a second deposition process to form a second polysilicon layer on the surface of the first polysilicon layer; and
introducing the gas containing the dopants into the trench to diffuse the dopants into the second polysilicon layer.

7. The method for preparing a trench capacitor structure of claim 6, wherein the dopants are N⁺ type.

8. The method for preparing a trench capacitor structure of claim 7, wherein the dopants are arsenic ions.

9. A method for preparing a trench capacitor structure, comprising the steps of:
forming at least one trench in a substrate;
forming a buried bottom electrode on a lower outer surface of the trench;
forming a dielectric layer covering an inner sidewall of the trench;
performing a plurality of deposition processes and introducing a gas containing dopants into the trench at an interval of the deposition processes to form a plurality of conductive layers filling the trench; and
removing a portion of the conductive layers from a top portion of the trench to form a top electrode in a lower portion of the trench.

10. The method for preparing a trench capacitor structure of claim 9, wherein the deposition processes form a plurality of polysilicon layers on the inner sidewall of the trench, and the dopants are diffused into the polysilicon layers.

11. The method for preparing a trench capacitor structure of claim 9, wherein the step of forming a top electrode in the lower portion of the trench comprises:
performing a first deposition process to form a first polysilicon layer on the inner sidewall of the trench;
introducing the gas containing the dopants into the trench to diffuse the dopants into the first polysilicon layer;
performing a second deposition process to form a second polysilicon layer on the surface of the first polysilicon layer; and
introducing the gas containing the dopants into the trench to diffuse the dopants into the second polysilicon layer.

12. The method for preparing a trench capacitor structure of claim 11, wherein the dopants are N⁺ type.

13. The method for preparing a trench capacitor structure of claim 12, wherein the dopants are arsenic ions.
